(19) United States
(12) Patent Application Publication
(10) Pub. No.: US 2008/0099430 A1
(43) Pub. Date: May 1, 2008

(54) Method for connecting array of optical waveguides to an array of optical fibers with very small pitch

(76) Inventors: David Brooks, Hod Hasharon (IL); Eli Arad, Tel Aviv (IL); Serge Steinblatt, Ra'anana (IL)

Correspondence Address: EMPK & Shiloh, LLP, 116 JOHN ST,, SUITE 1201, NEW YORK, NY, 10038, US

(21) Appl. No.: 11/589,247

(22) Filed: Oct. 30, 2006

(51) Int. Cl. B29D 11/00; C23F 1/00; H01L 21/306; G02B 6/255

(52) U.S. Cl. 216/24; 216/90; 216/85; 156/345.11; 156/345.15; 385/98

(57) ABSTRACT

A method and apparatus are provided to decrease the diameter of the end of an optical fiber in order to make it possible to arrange optical fibers in an array with very high pitch. Also provided is an optical device comprising a plurality of optical fibers, each fiber formed of a body having a first diameter and an external coating, wherein end portions of the fibers have no external coating thereon and have a second diameter which is smaller than the first diameter.

### BACKGROUND OF THE INVENTION

The use of fiber optic based communication infrastructure is rapidly evolving, dictating intensive search for fiber optical infrastructure with more rapid communication rate, having smaller volume and supporting more channels of communication. Some fields of endeavor are the FTTP (Fiber To The Premises), FTTH (Fiber To The Home), FTTC (Fiber To The Curb) and the like, dealing with equipment for distribution of fiber optic based communication from one physical channel to a plurality of physical channels. One of the network concepts for the FTTP, FTTH or FTTC is the so-called PON (Passive Optical Network). In this network configuration, the fibers are distributed from a central office to the premises, through a series of cascaded splitters, splitting one channel to a number of channels, e.g. to 128 channels.

There are several technologies to produce the splitters, like fused conical fiber splitters. Another family of splitters is based on integrated optics splitting devices based on Planar Lightwave Circuit (PLC), which perform the splitting action, and to which one input fiber is optically coupled to an input port on one side, and a plurality of fibers are optically coupled to a plurality of output ports. The plurality of output fibers may be arranged in an array. The standard pitch of the array to arrange plurality of fibers is dictated by the standard fiber diameter the nominal size of which is 125 microns. Therefore the pitch of the array is usually twice that of the fiber diameter, i.e. 250 microns or slightly larger than that of fiber diameter usually 127 microns. FIG. 1 schematically illustrates a waveguide splitting unit connected to fibers according to known art. FIGS. 2A and 2B schematically illustrates two bundles of coated fibers arranged in an interlaced form according to known methods. These known solutions suffer of several drawbacks. In large count output channels devices, it dictates a PLC based device because the width of the PLC must be at least the pitch of the fiber array times the number of fibers. This in turn, reduces the number of PLC fabricated per wafer, and also naturally reduces wafer yield. Also, since the PLC becomes wide, the radii of the waveguides especially those at the extremes become very small which causes additional optical propagation loss inside the device. Therefore, the ability to reduce the width of the PLC by reducing output waveguide pitch may remove the mentioned drawbacks.

### SUMMARY OF THE INVENTION

The present invention introduces a method for aligning tips of optical fibers having an initial outer diameter, from at least two bundles of fibers, in a linear array with high pitch which comprises stripping off coating from said tips of said fibers, dipping the stripped tips into an etching solution to controllably lower the outer diameter of the tips to a desired final outer diameter that is smaller than the initial outer diameter and forming a substantially linear array of said stripped and etched tips by interleaving them. In some embodiments the etching solution may be Hydrofluoric (HF) acid. In further embodiments the duration of etching may be controlled to provide for different diameters along the etched tip. According to yet another embodiment of the invention an apparatus is provided to controllably expose tips of optical fibers to an etching solution to provide for controlled etched diameter of a tip of the fiber.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1 and 2 are illustration of connection of fibers to an optical splitter as known in the art.

FIG. 3 is a schematic illustration of system and method for controlling the outer diameter of optical fibers according to embodiments of the present invention;

FIGS. 4 and 5 are schematic illustrations of cylindrical etched tips and conical plus cylindrical etched tips respectively according to some embodiments of the present invention; and

FIGS. 6 and 7 are schematic flow charts illustrating methods of controlling the outer diameter of optical fibers according to some embodiments of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

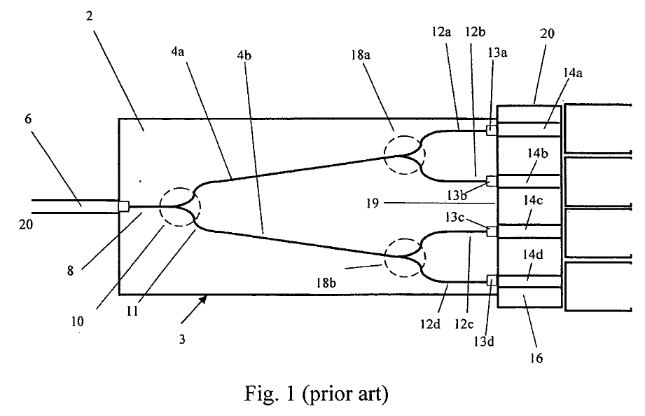

FIG. 1 illustrates a waveguide splitting unit 2 with two cascaded stages of splitters. Splitting unit 2 may comprise more stages of splitters but the principles of the invention will be demonstrated herein after with respect to only two stages of splitters. Yet, it would be apparent to a person skilled in the art that the principles applicable for a 2-stage splitting unit, as described in more details below, are also applicable to more stages of splitters. Splitting unit 2 may comprise a first splitting stage 10 and a second splitting stage 18, comprising splitters 18a and 18b. Each of the splitting stages may be designed to split a ray of light received from a waveguide into two waveguides. Thus, light entering splitter 10 from waveguide 8 may be split into waveguides 4a and 4b. Similarly, light traveling in waveguides 4a and 4b may be split, in splitting stage 18, to waveguides 12a, 12b, 12c and 12d respectively. Waveguides 12a-12d, may be connected to output ports 13a-13d respectively. Fibers 14a-14d may be optically coupled to output ports 13a-13d. In some embodiments, fibers 14a-14d may be arranged as an array, for example by means of array holder unit 20. In order to increase the number of outputs supported by a single splitting unit 2 and as a result—the number of splitting stages, several physical considerations need to be taken into consideration. One such consideration is the radius of curvature 11 used in the realization of a splitter. The bigger the radius the better the optical/spectral performance of the splitter. Another such consideration is the distance between two consecutive waveguides in splitting unit 2. Another consideration is the fact that splitters arranged in the substrate of splitting unit 2 are produced typically in one plane within the substrate and therefore the output ports 14 will typically be arranged along a substantially straight line. In order to provide for a larger number of outputs from splitting unit 2 this distance should be as small as possible.

Typically, the diameter of a waveguide in a substrate of splitting unit 2 is smaller than the diameter of a typical fiber connected to it. Thus, the number of output ports that may be arranged on the output face of splitting unit 2 is dictated primarily by the diameter of fibers 14. The smaller the pitch of waveguides 12a-12d is the bigger is the radius of curvatures 11 of splitters 10, 18a and 18b. Thus, when the array of output ports 13a-13d is made with smaller pitch it is beneficial both in allowing for more output ports in a single splitting unit 2 and for improving the optical performance of curvatures 11 of splitters 10, 18a and 18b. For a given radius of curvatures 11 of splitter 10, 18a and 18b, the splitting unit 2 may be of much smaller length and width if the pitch of the waveguides 13 is smaller.

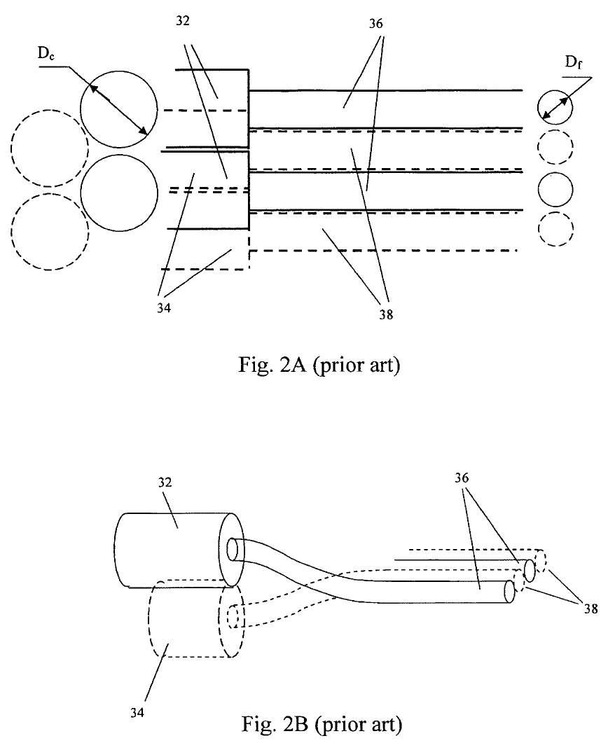

Standard fiber 14a-14d may typically have an outer diameter D_{f} of 125 μm (if made of glass) and a coating with diameter D_{c} of 250 μm. For several practical reasons, such as preventing of fan-out of a bundle of fibers, it is advantageous to arrange the fibers so that their tips form a substantially-linear array. When fibers in this linear array are arranged closely to each other the linear pitch of the fibers is substantially 250 or a bit higher, as dictated by the outer diameter of the coating of the fiber. FIGS. 2A and 2B illustrate a top and 3-D view, respectively, of two bundles of coated fibers arranged in an interleaved form. A first bundle 32 is represented in FIGS. 2A and 2B by solid lines and is arranged so that the coating of the fibers are close to each other, as may be seen on the left side of the drawings. In FIG. 2A left of the left end of coated fibers 32, 34 there are two couples of circles which illustrate, respectively, the side view of bundles 32, 34 when placed close to each other. The stripped fibers 36 of the first bundle are represented also by solid lines. A second bundle of coated fibers 34 is represented by dashed lines. The stripped fibers 38 of the second bundle are represented also by dashed lines. Due to reduction of substantially half of the outer diameter of the fibers by the removal of the coating, the stripped fibers of the two bundles may be interleaved and aligned along a substantially straight line, as illustrated by the solid line and dashed lines circles drawn right of the right end of stripped fibers 36, 38. FIG. 2B illustrates in a partial isometric 3-D illustration the arrangement described by FIG. 2A. It would be noted that first bundle 32 and second bundle 34 may be equal to each other and in different configuration the fibers may be different from each other.

Yet, this solution is limited also, as it may provide for pitch of not smaller than 125 μm. Thus the number of output ports in a given splitting unit 2 having a given operational length of its facet 19 to which waveguides 13n (where n indicates the number to which the input beam is split to) connect is dictated primarily by the outer diameter of fibers 14n.

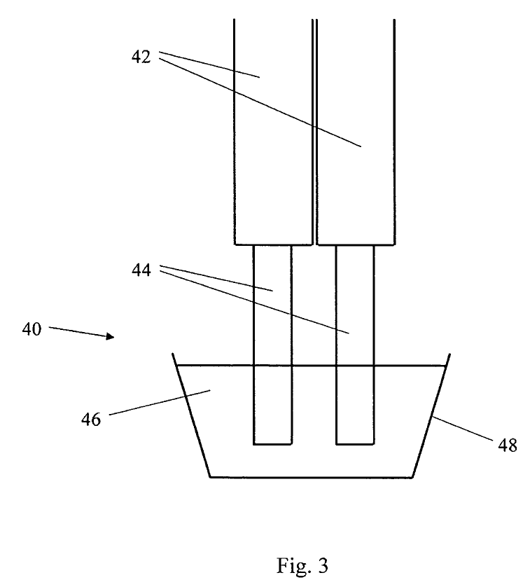

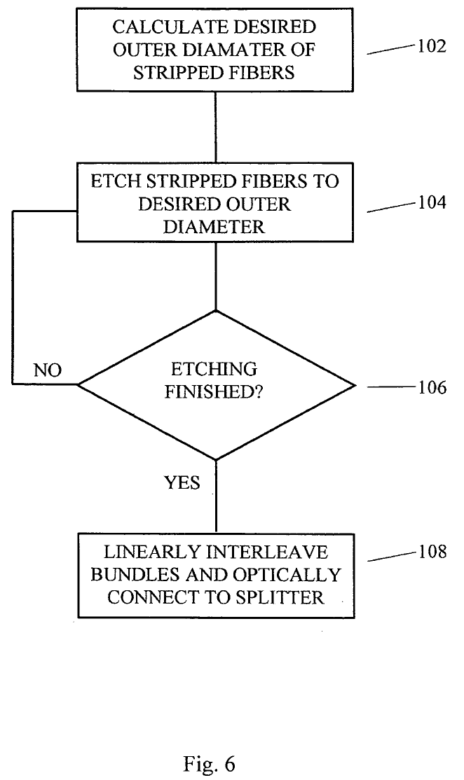

Attention is made now to FIG. 3, which is a schematic illustration of system 40 for controlling the outer diameter of optical fibers 44. Attention is also made to FIG. 6, which is a schematic flow chart illustrating a method of controlling the outer diameter of optical fibers according to some embodiments of the present invention. System 40 may comprise container 48 which may contain chemical solution 46 which is adapted to chemically etch the stripped edges 44 of coated fibers 42. Chemical solution may be any solution that controllably etches fibers 44, such as Hydrofluoric (HF) acid or any suitable other solution. Once the desired outer diameter of fibers' edges 44 is done (block 102) stripped off fibers 44 may be dipped into chemical solution 46 (block 104) until (block 106), by chemical etching, the outer diameter of edges 44 is reduced to a desired size. The etching may be controlled, for example, by setting the concentration of the solution and the time of process according to predefined tables, or based on actual prior accumulating experience. The etching may take from several minutes to about an hour depending on the solution concentration and the amount of etching needed. When the etching process has reached the desired outer diameter of edges 44 of fibers 42 the bundle of fibers is picked out of solution 46 and, if required, undergoes post etching process (block 108).

The etched diameter can be controlled by measuring the etching process time for given process features such as type of material of the fiber, concentration of the acid, etc. The etching rate may be measured experimentally or given from data sheets or similarly. Based on this information the desired final diameter may be controlled. When a desired diameter has been reached the tip in process may be pulled out of the etching solution. The etched diameter can be also controlled by a vision system that may include a vision sensor and a computer that is able to compare in real time the actual etched diameter to the desired diameter and issue a STOP signal on time, to pull the fiber out of the solution.

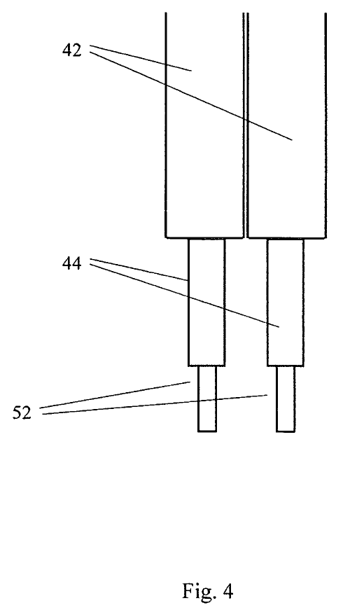

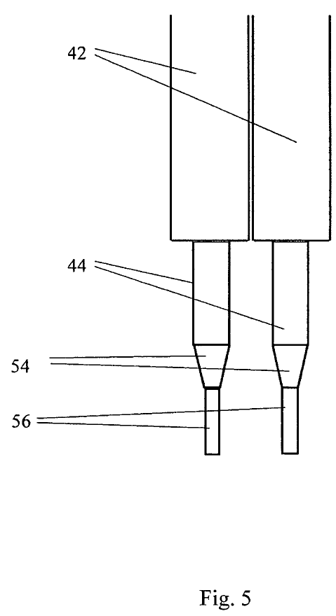

Attention is made now to FIGS. 4 and 5 which schematically illustrate cylindrical etched tips and conical plus cylindrical etched tips respectively according to some embodiments of the present invention. While etched, the fiber tips 44 may be pulled out from etching solution 46 at once to create a one-diameter, cylinder like, etched tip 52. Other forms of tips may be formed. For example, if tip 44 is gradually pulled out from the solution, when section 54 emerges from the solution and rapidly afterwards section 54 will be formed as a conical section while portion 56 being proximal to the end of fiber 44 is formed as a cylinder. Thus various forms may be produced by the control of the time each portion of the tip of fiber 44 is exposed to the etching solution, such as conical, conical with non-linear sides, or any other tapering shape depending on the profile in time of dipping the tips in and pulling them from the etching solution. This enables the use of a fiber with a very small diameter proximal to its tip yet being physically reinforced portions behind it since it is necessary that only the end of the fibers which are attached to the splitting device 2 (FIG. 1) will have the smallest diameter. The diameter can gradually be increased to the original one (125 μm). This might prevent also any stress and it will strengthen the structure.

The desired outer diameter may be calculated based on the number of bundles that need to be interleaved. Thus, while for interleaving of two bundles of fibers according to the present invention no etching is required, in order to interleave three bundles of fibers the outer diameter of a 125 μm should be reduced to substantially 80 μm and in order to interleave four bundles the outer diameter of fibers 44 will have to be reduced to substantially 60 μm. Once the outer diameter of edges 44 of the fibers of the bundles have been reduced to the desired size interleaving may be done (block I 10) according to the principles explained with respect to FIG. 2 above.

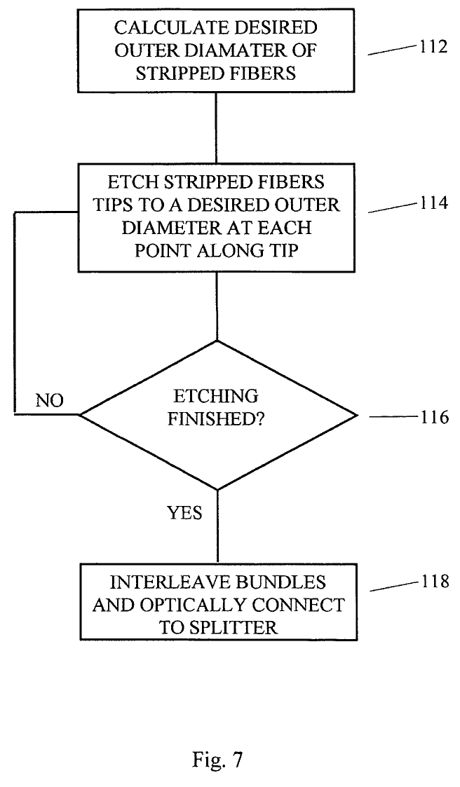

Attention is made now to FIG. 7, which is schematic block diagram illustrating a method of controlling the outer diameter of optical fibers according to some embodiments of the present invention. In order to form a linear array of optical fibers with high pitch according to the invention the desired outer diameter of the tips of the fibers should be calculated as in block 112. The tips than should be dipped in an etching solution as in block 114. The actual etched diameter is measured or calculated and a decision to stop etching is taken accordingly, as in block 116. Once the tips have the desired outer diameter they can be formed in a linear array with high pitch as depicted in block 118.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A method for aligning tips of optical fibers having an initial outer diameter, from at least two bundles of fibers, in a linear array with very small pitch, the method comprising:
stripping off coating from said tips of said fibers;
dipping said stripped tips into an etching solution to controllably decrease the outer diameter of said tips to a desired final outer diameter being smaller than said initial outer diameter; and
forming a substantially linear array of said stripped and etched tips by closely interleaving said etched tips.

2. The method of claim 1 wherein said etching solution is Hydrofluoric (HF) acid.

3. The method of claim 1 wherein decreasing the outer diameter of said tips is controlled by the duration of said dipping.

4. The method of claim 3 wherein the outer diameter of said tips is decreased gradually along at least a portion of said tips to etch a substantially conical portion of said tips.

5. An apparatus comprising:
a container with etching solution; and
an arrangement to controllably dip at least one uncoated end of an optical fiber in said etching solution to reduce the diameter of at least a portion of said end.

6. The apparatus of claim 5 further comprising a time-based controller to control the time said end of said at least one fiber is dipped in said etching solution.

7. The apparatus of claim 6 wherein said controller comprises a vision system able to measure in real time the diameter of said end of said at least one fiber when in said etching solution.

8. The apparatus of claim 6 wherein said controller provides a varying rate of pulling of said of said end of said at least one fiber from said etching solution.

9. An optical device comprising a plurality of optical fibers, each fiber comprising:
a body having a first diameter and an external coating,
wherein end portions of the fibers are arranged in an array having a very small pitch,
the end portions of the fibers having no external coating thereon and having a second diameter which is smaller than the first diameter.

10. A method for aligning tips of optical fibers having an initial outer diameter, in an array with very small pitch, the method comprising:
stripping off coating from said tips of said fibers;
dipping said stripped tips into an etching solution to controllably decrease the outer diameter of said tips to a desired final outer diameter smaller than said initial outer diameter; and
forming the array of said stripped and etched tips by arranging the tips in a desired manner.
